(19) United States
(12) Patent Application Publication
(10) Pub. No.: US 2016/0211687 A1
(43) Pub. Date: Jul. 21, 2016

(54) CHARGING APPARATUS, CHARGING DEVICE AND CABLE MANAGEMENT MEMBER

(71) Applicant: AVer INFORMATION INC., New Taipei City (TW)

(72) Inventors: YU-JUNG WANG, NEW TAIPEI CITY (TW); CHIH-HUNG CHENG, NEW TAIPEI CITY (TW)

(21) Appl. No.: 14/799,198

(22) Filed: Jul. 14, 2015

(30) Foreign Application Priority Data
Jan. 19, 2015 (TW) 104101715

(51) Int. Cl. H02J 7/00; H05K 7/14

(52) U.S. Cl. CPC H02J 7/0042; H02J 7/0013; H05K 7/1491

(57) ABSTRACT

A charging device is for charging at least one electronic device and fixing a cable which is connected to the at least one electronic device. The charging device includes a tray, a power supply part, at least one partition member and at least one cable management member. The tray has a loading zone. The power supply part is connected to the tray. The at least one partition member is disposed on the tray. The loading zone is divided into a plurality of loading sub-zones by the at least one partition member, and each of the loading sub-zones is for housing at least one electronic device. The at least one cable management member is disposed on the at least one partition member for fixing the cable.

### CROSS-REFERENCE TO RELATED APPLICATIONS

This non-provisional application claims priority under 35 U.S.C. § 119(a) on Patent Application No(s). 104101715 filed in Taiwan, R.O.C. on Jan. 19, 2015, the entire contents of which are hereby incorporated by reference.

### TECHNICAL FIELD

The present disclosure relates to a charging apparatus, a charging device and a cable management member, and more particularly to a charging apparatus that charges electronic devices.

### BACKGROUND

In recent years, tablet computers and other kinds of mobile devices have widely been used in learning and teaching activities. For example, these electronic devices have been used in schools or cram schools, etc. Every student can use their own tablet computer to interact with many interactive applications installed in the tablet computers.

In such cases, users usually need to charge their electronic devices, e.g., tablet computers, because battery levels of the tablet computers often run low during class. However, classes or other teaching environments only have a few power outlets or receptacles for recharging. Hence, manufacturers are constantly trying to develop an apparatus for housing and charging multiple tablet computers, for example, a charging cart or a charging cabinet.

However, traditional charging carts are universal serial bus (USB) type, and locations of the USB ports are hard to find, which means it is not convenient for users to connect their tablet computers with the USB ports. In addition, the charging cart is able to house many tablets, so the number of cables disposed inside is increased with the increase of the number of tablet computers, and thus the cables are likely to get tangled with each other. Consequently, it is hard for users to find the USB ports to plug into, and the space in the charging cart is jammed with many cables and is not large enough to house the electronic devices.

### SUMMARY

One embodiment of the disclosure provides a charging device for charging at least one electronic device and fixing a cable which is connected to the at least one electronic device. The charging device includes a tray, a power supply part, at least one partition member and at least one cable management member. The tray has a loading zone. The power supply part is connected to the tray. The at least one partition member is disposed on the tray. The loading zone is divided into a plurality of loading sub-zones by the at least one partition member, and each of the plurality of loading sub-zones is for housing the at least one electronic device. The at least one cable management member is disposed on the at least one partition member for fixing the cable.

Another embodiment of the disclosure provides a cable management member for being disposed on an object and fixing a cable. The cable management member includes a main clip and at least two sub-clips. The main clip has a main clipping opening for being retained on the object. The at least two sub-clips are disposed on the main clip, and each of the sub-clips has a sub-clipping opening for retaining the cable.

Yet another embodiment of the disclosure provides a charging apparatus for charging at least one electronic device and fixing a cable which is connected to the at least one electronic device. The charging apparatus includes a case body and at least one charging device. The case body has an accommodation space. The at least one charging device is removably disposed in the accommodation space. The at least one charging device includes a tray, a power supply part, at least one partition member and at least one cable management member. The tray has a loading zone. The power supply part is connected to the tray. The at least one partition member is disposed on the tray. The loading zone is divided into a plurality of loading sub-zones by the at least one partition member, and each of the plurality of loading sub-zones is for housing the at least one electronic device. The at least one cable management member is disposed on the at least one partition member for fixing the cable.

### BRIEF DESCRIPTION OF THE DRAWINGS

FIG. 1 is a schematic perspective view of a charging apparatus for housing electronic devices according to one embodiment of the disclosure.

FIG. 2 is a top cross-sectional view of the charging apparatus according to one embodiment of the disclosure.

FIG. 3 is a schematic perspective view of the charging device for housing an electronic device and cables according to one embodiment of the disclosure.

FIG. 4 is a partial enlarged view of FIG. 3.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

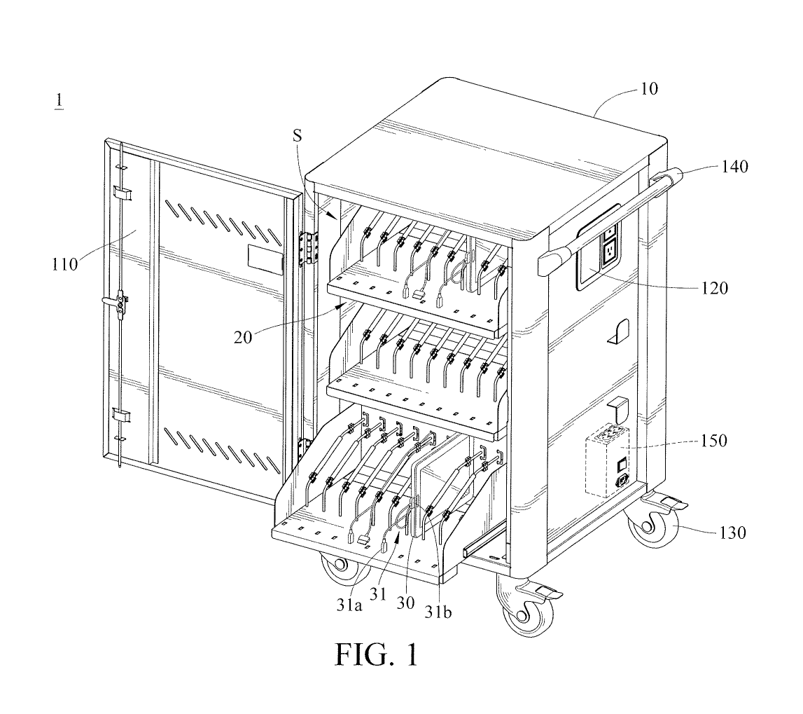

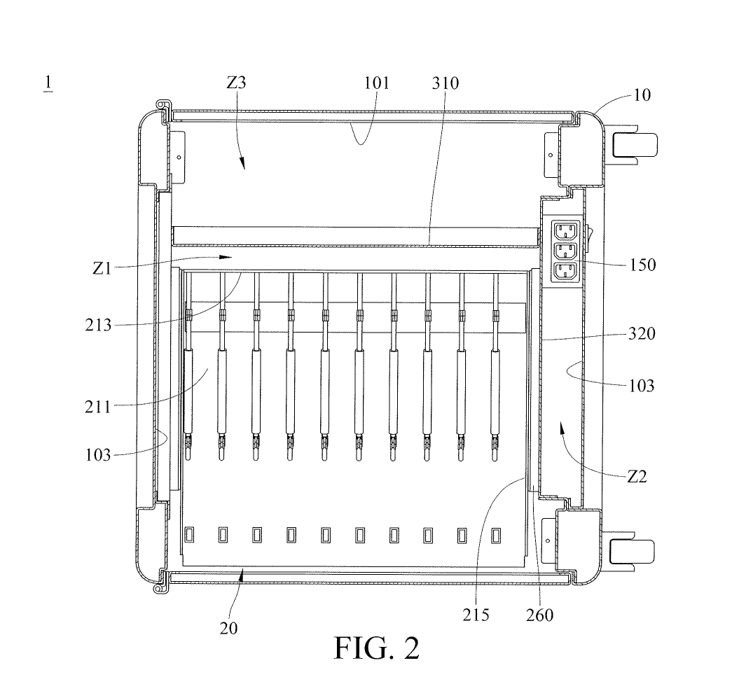

Please refer to FIG. 1 and FIG. 2. FIG. 1 is a schematic perspective view of a charging apparatus for housing electronic devices according to one embodiment of the disclosure. FIG. 2 is a top cross-sectional view of the charging apparatus according to the embodiment of the disclosure. The embodiment of the disclosure provides a charging apparatus 1 for charging a plurality of electronic devices 30 and fixing a plurality of cables 31 connected to the electronic devices 30. For example, the aforementioned charging apparatus is a charging cart with universal serial buses (USB) ports. For example, the electronic device 30 is a smart phone or a tablet computer.

In this embodiment, the charging apparatus 1 includes a case body 10, a plurality of charging device 20, a first partition member 310 and a second partition member 320.

In detail, the case body 10 includes an accommodation space S, a rear wall surface 101 and two side wall surfaces 103. As shown in FIG. 1, the accommodation space S is for housing the plurality of charging devices 20, but the disclosure is not limited to the quantity of the charging device 20. The two side wall surfaces 103 are connected to two sides of the rear wall surface 101, respectively, and the two sides of the rear wall surface 101 are opposite to each other. It is understood by people skilled in the art that the accommodation space S is formed by the rear wall surface 101, the two side wall surfaces 103 and some other wall surfaces.

The charging device 20 is removably disposed in the accommodation space S, that is, the charging device 20 is able to be moved to protrude outward from the accommodation space S or stored in the accommodation space S.

Please refer to both FIG. 1 and FIG. 2, the first partition member 310 and the second partition member 320 are located in the accommodation space S of the case body 10. Specifically, the first partition member 310 is located between the charging device 20 and the rear wall surface 101 of the case body 10, and the second partition member 320 is located between the charging device 20 and one of the side wall surfaces 103 of the case body 10. Therefore, the accommodation space S of the case body 10 is divided into a storing zone Z1, a power supply zone Z2 and a cable-receiving zone Z3 by the rear wall surface 101, the side wall surface 103, the first partition member 310, the second partition member 320 and the charging device 20, as shown in FIG. 2. In addition, purposes of each zone Z1-Z3 will be described in the following description.

On the one hand, it is understood by people skilled in the art that the first partition member 310 and the second partition member 320 are only used for dividing spaces, and the disclosure is not limited to the configurations of the first partition member 310 and the second partition member 320. On the other hand, in some embodiments, the case body 10 is structured to be without the aforementioned first partition member 310 and second partition member 320.

In addition, the charging apparatus 1 further includes a power supply 150 disposed in the case body 10. For example, the power supply 150 is disposed in the power supply zone Z2. The power supply 150, for example, is an extension cable assembly, and the power supply 150 is able to provide power for the electronic devices 30 by connecting an external power. Therefore, in this embodiment, each of the charging devices 20 is electrically connected to the power supply 150 in the power supply zone Z2 via extension cables (not shown), in order to provide power for the charging devices 20. For example, most of the extension cables are arranged in the cable-receiving zone Z3 of the charging apparatus 1.

Furthermore, as shown in FIG. 1, in this and some embodiments, the charging apparatus 1 further includes a door plate 110, an extra outlet 120, a plurality of wheels 130 and a handle 140.

The door plate 110 is pivotally connected to a side of the case body 10. Specifically, the door plate 110 is disposed on an edge of the accommodation space S. Accordingly, the door plate 110 is pivotally rotated relative to the case body 10 for covering or exposing the accommodation space S. The extra outlet 120 is disposed on a side surface of the case body 10, the extra outlet 120 is electrically connected to the power supply 150 in the case body 10, and there is a plurality of receptacles disposed on the extra outlet 120 for being electrically connected to extra electronic devices. The wheels 130 are disposed on a bottom side of the case body 10, and thus the case body 10 is able to slide on a floor or a ground. The handle 140 is disposed on a side surface of the case body 10 for being pushed by users to move the case body 10.

It is understood by people skilled in the art that the present disclosure is not limited to the door plate 110, the extra outlet 120, the plurality of wheels 130 and the handle 140, which means these components are optional.

The charging device 20 in the case body 10, as shown in FIG. 1, is described in the following description.

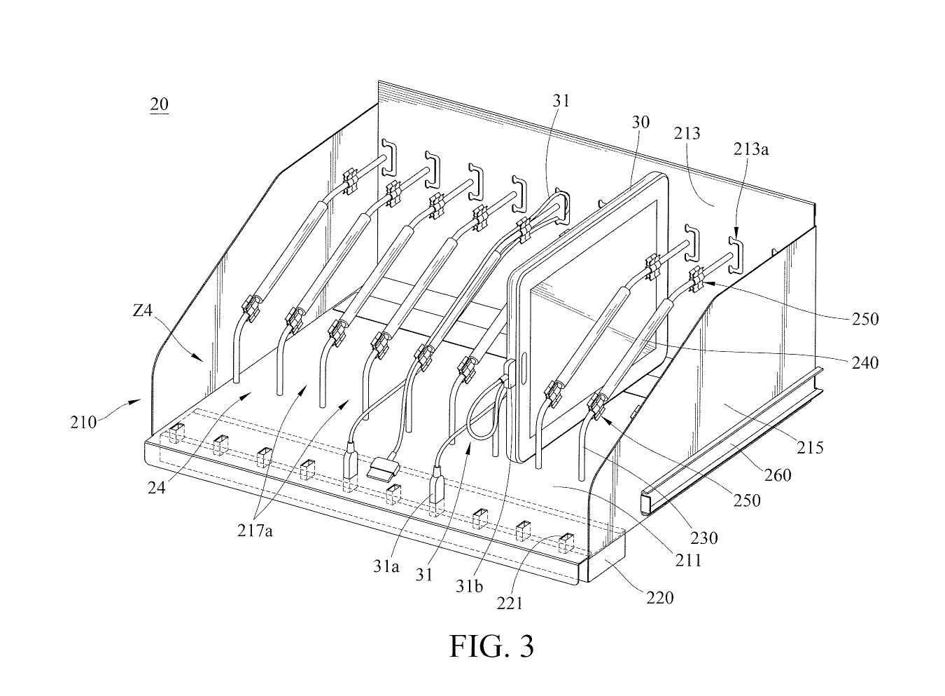

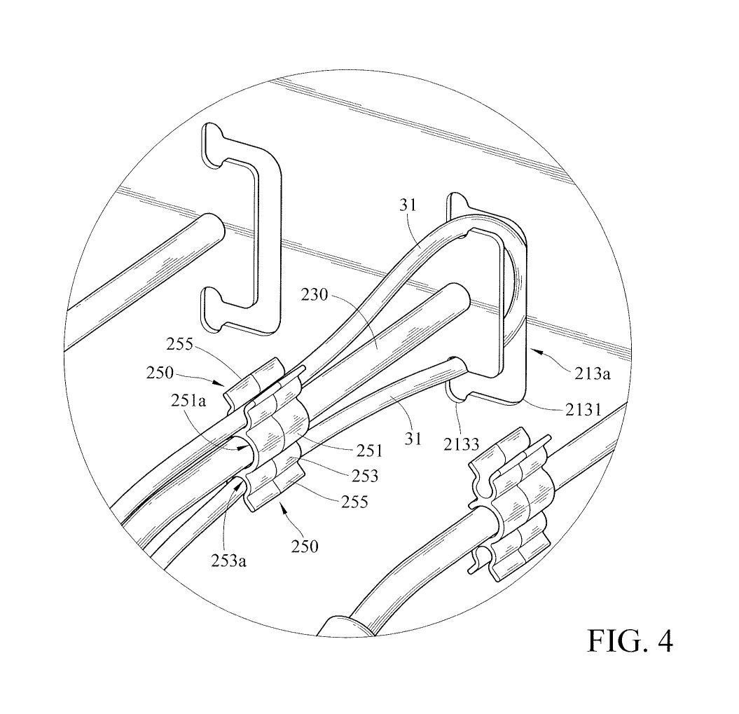

Please refer to FIG. 3 and FIG. 4. FIG. 3 is a schematic view of the charging device for housing an electronic device and cables according to one embodiment of the disclosure. FIG. 4 is a partial enlarged view according to FIG. 3. In this embodiment, the charging device 20 includes a tray 210, a power supply part 220, a plurality of partition members 230 and a plurality of cable management members 250.

In detail, the tray 210 includes a bottom plate 211, a rear plate 213 and two side plates 215. The bottom plate 211 is connected to the rear plate 213. Each of the two side plates 215 is respectively connected to the bottom plate 211 and the rear plate 213. The two side plates 215 are disposed on two ends of the bottom plate 211, respectively, and are disposed on two ends of the rear plate 213, respectively. That is, the bottom plate 211 is disposed between the two side plates 215, and the rear plate 213 is disposed between the two side plates 215 as well. Therefore, the bottom plate 211, the rear plate 213 and the two side plates 215 form a loading zone Z4 exposing to the outside of the charging device 20. The loading zone Z4 is for housing the electronic devices 30.

Relative positions of the above-mentioned zones Z1˜Z4 in the accommodation space S and the tray 210 are more clearly described in the following description with FIG. 2. As shown in FIG. 2, the rear plate 213 is located between the rear wall surface 101 of the case body 10 and the bottom plate 211. The first partition member 310 is located between the rear wall surface 101 of the case body 10 and the rear plate 213. The second partition member 320 is located between the side wall surface 103 of the case body 10 and the side plate 215. That is, the storing zone Z1 is located between the first partition member 310 and the rear plate 213. The power supply zone Z2 is located between the side wall surface 103 of the case body 10 and the side plate 215. The cable-receiving zone Z3 is located between the rear wall surface 101 of the case body 10 and the second partition member 320.

In this embodiment, the power supply part 220 is connected to an end of the bottom plate 211. Specifically, as shown in FIG. 3, the power supply part 220 and the rear plate 213 are located on two ends of the bottom plate 211, respectively. A plurality of universal serial buses (USB) ports 221 is disposed on the power supply part 220.

In this embodiment, the plurality of partition members 230 is disposed on the tray 210. Furthermore, the plurality of partition members 230 is disposed between the bottom plate 211 and the rear plate 213 of the tray 210. For example, in this embodiment, each of the partition members 230 is bar-shaped, and two ends of each of the partition members 230 is disposed on the bottom plate 211 and the rear plate 213, respectively. For example, the partition members 230 are screwed into the bottom plate 211 and the rear plate 213, respectively. In addition, the partition members 230 are spaced apart by a specific distance, and thus the loading zone Z4 in the tray 210 is divided into a plurality of loading sub-zones 217a by the partition members 230. Specifically, the adjacent partition members 230 and the bottom plate 211 of the tray 210 form the loading sub-zones 217a. Accordingly, the electronic devices 30 are accommodated in the loading sub-zones 217a. However, the present disclosure is not limited to the quantity of the partition members 230, and the quantity of the partition members 230 is altered according to actual requirement. In such a case, the quantity of the loading sub-zones 217a is altered according to actual requirement.

The plurality of cable management members 250 is disposed on the partition members 230, respectively. In detail, as shown in FIG. 4, each of the cable management members 250 includes a main clip 251 and two sub-clips 253. The main clip 251 has a main clipping opening 251a for being retained on the partition member 230. For example, in this embodiment, the main clip 251 is clipped on the bar-shaped partition members 230 via the main clipping opening 251a, so the partition members 230 are clipped into the main clipping opening 251a, allowing the main clip 251 to be retained on the partition member 230. The two sub-clips 253 are disposed on the main clip 251. For example, the two sub-clips 253 are disposed on two ends of the main clip 251 that are opposite to each other, respectively, and thus the sub-clips 253 are spaced apart from each other. That is, the two ends of the main clip 253 are the farthest ends on the main clip 251. Furthermore, each of the sub-clips 253 includes a sub-clipping opening 253a and two extending sections 255. Directions of the sub-clipping openings 253a are opposite to each other, and the two extending sections 255 are extend outward from two edges of the sub-clipping opening 253a, respectively. The sub-clipping opening 253a is for retaining the cable 31, and the two extending sections 255 are for guiding the cable 31 to be moved into the sub-clipping opening 253a. Consequently, the cable 31 which is retained by the two sub-clips 253 and is maintained at two farthest ends on the main clip 251.

In addition, please refer both FIG. 3 and FIG. 4, in this embodiment, there are a plurality of slots 213a disposed on the rear plate 213, the slots 213a communicate with the loading zone Z4 and the storing zone Z1. The cables 31 of the electronic devices 30 are able to pass through the rear plate 213 via the slots 213a.

In detail, each of the slots 213a has a bridge section 2131 and two holding sections 2133, the two holding sections 2133 are located on two ends of the bridge section 2131, respectively, the two ends of the bridge section 2131 are opposite to each other. The two holding sections 2133 communicate with the bridge section 2131.

Furthermore, in this embodiment, the charging device 20 further includes at least one protective member 240 and two sliding mechanisms 260.

In detail, the plurality of protective members 240 is disposed on the partition members 230, respectively. Specifically, each of the partition members 230 is sleeved by the protective member 240. The protective member 240 is made of plastic material. For example, the protective member 240 is made of foam or rubber. Accordingly, when the electronic device 30 is clipped or retained between the adjacent partition members 230, the protective member 240 is able to protect the electronic device 30 from an impact applying to the electronic device 30. It is understood by people skilled in the art that the protective members 240 are able to prevent the electronic devices 30 from directly contacting the partition members 230, thereby scratching the electronic devices 30.

Each of the sliding mechanisms 260 is movably connected between the tray 210 and the case body 10. As shown in FIG. 2 and FIG. 3, each of the sliding mechanisms 260 is disposed between the side plate 215 of the tray 210 and the side wall surface 103 of the case body 10. Hence, the tray 210 is movably connected on the case body 10, so that the tray 210 is moved to protrude outward from or stayed within the accommodation space S of the case body 10.

Operations of the charging apparatus 1 are described in the following description.

As shown in FIG. 3, users are able to insert a first port 31a of the cable 31 into the USB port 221, and a part of the wire of the cable 31 is retained on one of the cable management members 250 located on the partition member 230. In addition, the rest of the wire of the cable 31, which is too long and not required, is able to pass through the slot 213a, and thus the rest of the wire of the cable 31 is stored within the storing zone Z1. Thus, the cable 31 is retained in the holding sections 2133 of the slot 213a.

It is understood by people in the skill of art that a length of the rest of wire of the cable 31, which is stored in the storing zone Z1 by passing through the slot 213a from the loading zone Z4, is able to be adjusted by users. Thus, a length of the part of the cable 31 in the loading zone Z4 is more proper to allow the cable 31 to be retained on the partition member 230 smoothly. The cables 31 are easily managed and it prevents the cables from being tangled with each other. Also, because users are able to store the cable 31 into the storing zone Z1 by passing the cable 31 from the loading zone Z4 through the slot 213a, the rest of the cable 31, which is too long or not required, is stored in the storing zone Z1 behind the rear plate 213 of the tray 210. The length of the part of the cable 31 for charging the electronic device 30 is more appropriate. Consequently, the length of the cable 31 for charging the electronic device 30 is not too long and not tangled.

Hence, users are able to put the electronic device 30 into loading sub-zones 217a in the partition member 230, and connect a second port 31b of the cable 31 to the electronic device 30 for charging the electronic device 30.

Because the power supply part 220 is located adjacent to an opening of the accommodation space S where users may pick and place the electronic device 30. Therefore, the location of the power supply part 220 is obvious for users to find, and thus it is convenient for users to plug and unplug the cable 31 from the power supply part 220.

In addition, the cables 31 are normally retained and stored in each charging devices 20, and thus users are able to charge the electronic device 30 without carrying the cable 31 along. That is, the electronic device 30 is charged when the users connect the cable 31 to the electronic device 30 and put the electronic device 30 into the loading sub-zones 217a.

Since the two sub-clips 253, which retain the cable 31, are located at the two farthest ends of the main clip 251, respectively, thus the cable 31 is able to be maintained at the farthest ends on the main clip 251 for preventing from tangling the parts of the cable 31 which are too close to each other. In the same manner, the two holding sections 2133 of the slot 213a are located at two farthest ends of the bridge section 2131, thus the cable 31 is able to be retained in the two holding sections 2133 and maintained at two farthest ends of the slot 213a after passing through the slot 213a. It also helps to prevent the parts of the cable 31 from tangling with each other.

As shown in FIG. 4, an end of the partition member 230 which is disposed on the rear plate 213 is located between the two holding sections 2133, thus cable 31 is maintained at two ends of the partition member 230 which are opposite to each other for preventing cable 31 from tangling.

According to the cable management member, the charging device and the charging apparatus of the embodiments of the disclosure, because the cable management member is disposed on the partition member, and thus the cable, which is connected to the electronic device, is retained properly.

In addition, because the slots are disposed on the tray, the cable is able to pass through the slot and to be retained on the slot. Also, the part of the wire of the cable, which is too long and is not required, is stored in the storing zone between the charging apparatus and the charging device. It not only maintains an aesthetic appearance during charging but also prevents the parts of the cable, which are too close to each other, from tangling with each other as well as obstructing users to pick or place electronic devices.

What is claimed is:

1. A charging device for charging at least one electronic device and fixing a cable which is connected to the at least one electronic device, the charging device comprising:
a tray having a loading zone;
a power supply part being connected to the tray;
at least one partition member being disposed on the tray, the loading zone being divided into a plurality of loading sub-zones by the at least one partition member, and each of the plurality of loading sub-zones being for housing the at least one electronic device; and
at least one cable management member being disposed on the at least one partition member for fixing the cable.

2. The charging device according to claim 1, wherein the tray comprises a bottom plate and a rear plate, the bottom plate is connected to the rear plate, the rear plate has at least one slot, and the cable passes through the at least one slot.

3. The charging device according to claim 2, wherein the at least one partition member has two ends connected to the bottom plate and the rear plate, respectively.

4. The charging device according to claim 2, wherein the slot has a bridge section and two holding sections, the two holding sections communicates with two ends of the bridge section which are opposite to each other, respectively.

5. The charging device according to claim 4, wherein an end of the at least one partition member is located between the holding sections.

6. The charging device according to claim 4, further comprising at least one protective member, and the at least one partition member being sleeved by the at least one protective member.

7. The charging device according to claim 1, wherein the at least one cable management member comprises at least one clip for retaining the cable.

8. A cable management member for being disposed on an object and fixing a cable, the cable management member comprising:
a main clip having a main clipping opening for being retained on the object; and
at least two sub-clips being disposed on the main clip, and each of the sub-clips having a sub-clipping opening for retaining the cable.

9. The cable management member according to claim 8, wherein each of the sub-clips has two extending sections, the extending sections are disposed on two edges of the sub-clipping opening, respectively, and extend outward from the main clip.

10. The cable management member according to claim 8, wherein the quantity of the at least two of the sub-clips is two, the sub-clips are disposed on two ends of the main clip which are opposite to each other, respectively, and directions of the sub-clipping openings of the sub-clips are opposite to each other.

11. A charging apparatus for charging at least one electronic device and fixing a cable which is connected to the at least one electronic device, the charging apparatus comprising:
a case body having an accommodation space; and
at least one charging device being removably disposed in the accommodation space, and the at least one charging device comprising:
a tray having a loading zone;
a power supply part being connected to the tray;
at least one partition member being disposed on the tray, the loading zone being divided into a plurality of loading sub-zones by the at least one partition member, and each of the plurality of loading sub-zones for housing the at least one electronic device; and
at least one cable management member being disposed on the at least one partition member for fixing the cable.

12. The charging apparatus according to claim 11, further comprising a first partition member, the case body having a rear wall surface, the tray having a bottom plate and a rear plate, the bottom plate being connected to the rear plate, the rear plate being located between the rear wall surface and the bottom plate, the first partition member being located between the rear wall surface and the bottom plate, the accommodation space having a storing zone being located between the rear plate and the first partition member, the rear plate having at least one slot, and the at least one slot communicating with the storing zone such that the cable penetrates through and is stored in the storing zone.

13. The charging apparatus according to claim 12, further comprising a power supply and a second partition member, the case body having a side wall surface being connected to the rear wall surface, the tray having a side plate being respectively connected to the bottom plate and the rear plate, the second partition member being located between the side plate and the side wall surface, the accommodation space having a power supply zone being located between the second partition member and the side wall surface, and the power supply being located in the power supply zone.

14. The charging apparatus according to claim 13, further comprising an extra outlet being disposed on the case body, and the extra outlet being electrically connected to the power supply.

15. The charging apparatus according to claim 11, wherein the at least one cable management member has at least one clip for retaining the cable.

16. The charging apparatus according to claim 11, further comprising two sliding mechanisms being located on two sides of the tray which are opposite to each other, respectively, and the sliding mechanisms being movably connected to the tray and the case body, respectively.

17. The charging apparatus according to claim 11, further comprising a door plate and a plurality of wheels, the door plate being pivotally disposed to a side edge of the case body, and the wheels being disposed on a bottom side of the case body.
